(19) United States
(12) Patent Application Publication
(10) Pub. No.: US 2008/0311754 A1
(43) Pub. Date: Dec. 18, 2008

(54) LOW TEMPERATURE SACVD PROCESSES FOR PATTERN LOADING APPLICATIONS

(75) Inventors: BALAJI CHANDRASEKARAN, Santa Clara, CA (US); Douglas E. Manning, Kuna, ID (US); Nitin K. Ingle, Santa Clara, CA (US); Rong Pan, San Francisco, CA (US); Zheng Yuan, Fremont, CA (US); Sidharth Bhatia, Sunnyvale, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/137,372

(22) Filed: Jun. 11, 2008

Related U.S. Application Data
(60) Provisional application No. 60/944,340, filed on Jun. 15, 2007.

(51) Int. Cl. H01L 21/311; H01L 21/31

(52) U.S. Cl. 438/696; 438/787; 257/E21.24; 257/E21.249

(57) ABSTRACT

A method of improving pattern loading in a deposition of a silicon oxide film is described. The method may include providing a deposition substrate to a deposition chamber, and adjusting a temperature of the deposition substrate to about 250° C. to about 325° C. An ozone containing gas may be introduced to the deposition chamber at a first flow rate of about 1.5 slm to about 3 slm, where the ozone concentration in the gas is about 6% to about 12%, by wt. TEOS may also be introduced to the deposition chamber at a second flow rate of about 2500 mgm to about 4500 mgm. The deposition rate of the silicon oxide film is controlled by a reaction rate of a reaction of the ozone and TEOS at a deposition surface of the substrate.

### CROSS-REFERENCES TO RELATED APPLICATIONS

The present application claims benefit under 35 USC 119(e) of U.S. provisional Application No. 60/944,340, filed on Jun. 15, 2007 entitled “Low Temperature SACVD Processes For Pattern Loading Applications,” the content of which is incorporated herein by reference in its entirety.

### BACKGROUND OF THE INVENTION

As the device density and functionality of semiconductor integrated circuit chips continue to increase, new solutions are needed to form these devices at ever smaller scales. Conventional photolithography has been used successfully to form device patterns down to 65 nm scales. However, as the scales are reduced even further (e.g., sub-45 nm scales) challenges arise from physical limits on the resolution of optical lithography.

The resolution of a lithography system may be described by the Rayleigh Equation [R=k₁(λ/NA)], where k₁ is a proportionality constant that has a limiting value of 0.25 for a single exposure, λ is the wavelength of light used, and NA is the numerical aperture of the optics used. Each of these variables influence the optical resolution of photolithographic patterning techniques. For example, by increasing NA, decreasing the wavelength λ, and/or decreasing k₁ the resolution will be improved and photolithographic patterning can achieve smaller scales. However, there are many challenges to adjusting each of the variables to improve the resolution.

For example, increasing the value of the numerical aperture NA will require new high index immersion fluids and optical materials. However, the development of new materials with the required optical properties and a higher refractive index has proved challenging.

Decreasing the wavelength λ, is also encountering technical challenges as lower (i.e., deeper) UV wavelengths accessible by conventional excimer laser technology are being tested. While the 248 nm line has been implemented successfully for 100 nm scaling, and the 193 nm line has shown success for scaling to 65 nm and some 45 nm devices, moving to lower excimer wavelengths as been difficult. Attempts to develop photolithography for the 157 nm excimer line, for example, has so far not been successful. The challenges include limited availability of optical material (i.e., crystalline CaF₂ optics) and lack of immersion fluids with sufficiently high transmission and index of refraction. Moreover, even if these challenges can be met, the decrease in wavelength from 193 nm to 157 nm was not large enough to significantly improve the resolution of the photolithography done at 157 nm.

Development is also underway for extreme ultra-violet systems (EUV) that can generate wavelengths of light 10 to 15 times shorter than current 193 nm technology (e.g., 13.5 nm). These systems will require replacing immersion fluids and conventional optics with vacuum and fully reflective optics because most materials will absorb these short wavelengths. At present, development of these EUV systems has just started, and the development of new mask, source, and resist infrastructure is expected to take several years.

Another possibility to increase the resolution is to lower the k₁ value of the Rayleigh Equation through a double patterning process. One double patterning technique, known as lithographic double patterning, involves splitting a chip pattern having a k₁ value at or below 0.25 into to two or more separate mask patterns that have k₁ values greater than 0.25. The first mask pattern may be exposed and etched into a hardmask film before a photoresist cots the patterned hardmask. The second mask is aligned with the etched pattern before the photoresist is exposed and etched. The dual patterning an etching allows device structures to be formed on the surface with a scaling that is smaller than the resolution limit defined by the Rayleigh Equation.

While lithographic double patterning hold the promise of extending the current infrastructure for 193 nm photolithography to smaller scales, it also introduces significant technical challenges. These include the difficulty in achieving pattern to pattern overlay between the mask patterns at the precision needed. There are also some efficiency losses incurred by the increased number of photoresist deposition, patterning, and etching steps needed for patterning with multiple masks. Thus, there is a need for additional techniques to decrease device scale and increase device density in the fabrication of integrated circuit chips.

### BRIEF SUMMARY OF THE INVENTION

Embodiments of the invention include methods of improving pattern loading in a deposition of a silicon oxide film. The methods may include providing a deposition substrate to a deposition chamber, and adjusting a temperature of the deposition substrate to about 250° C. to about 325° C. An ozone containing gas may be introduced to the deposition chamber at a first flow rate of about 1.5 slm to about 3 slm, where the ozone concentration in the gas is about 6% to about 12%, by wt. TEOS may also be introduced to the deposition chamber at a second flow rate of about 2500 mgm to about 4500 mgm. The deposition rate of the silicon oxide film is controlled by a reaction rate of a reaction of the ozone and TEOS at a deposition surface of the substrate.

Embodiments of the invention may also include methods of forming and removing a sacrificial oxide layer. The methods may include the steps of forming a step on a substrate, where the step has a top and sidewalls, and forming a sacrificial oxide layer around the step by chemical vapor deposition of ozone and a silicon-precursor, where the oxide layer is formed on the top and sidewalls of the step. The methods may also include removing a top portion of the oxide layer and the step, and removing a portion of the substrate exposed by the removal of the step to form a etched substrate. The methods may further include removing the entire sacrificial oxide layer from the etched substrate.

Embodiments of the invention may still further include methods to incorporate a sacrificial oxide layer in a semiconductor gap formation process. The methods may include the steps of forming a photoresist layer on a substrate, and patterning the photoresist layer to form a step structure. The methods may also include forming the sacrificial oxide layer around the step structure by chemical vapor deposition of ozone and a silicon-containing precursor. A top portion of the oxide layer may be removed to form unconnected first and second oxide structures on opposite sidewalls of the step structure. The step structure between the oxide structures may be removed, as well as a portion of the underlying substrate that is not covered by the oxide structures to form an etched gap in the substrate. The methods may still further include removing the oxide structures from the etched substrate.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a drawing showing relationships of thicknesses and temperatures of a O₃/TEOS SACVD reaction according to an exemplary embodiment of the present invention;

FIG. 2 is a drawing showing relationships of deposition rates and O₃ amounts of a O₃/TEOS SACVD reaction according to an exemplary embodiment of the present invention;

FIG. 3 is a drawings showing relationships of deposition rates and TEOS flow rates at a processing temperature of about 250° C. of a O₃/TEOS SACVD reaction according to an exemplary embodiment of the present invention;

FIG. 4 is a drawing showing relationships of deposition rates and TEOS flow rates of a O₃/TEOS SACVD reaction with a low amount of O₃ according to an exemplary embodiment of the present invention;

FIGS. 5A and 5B are TEM images showing conformity of film deposition at a dense area and an open area, respectively, according to an exemplary embodiment of the present invention; and

FIG. 6 is a table showing characteristics of a film formed with the O₃ amount of about 2 L at a processing temperature of about 300° C. of a O₃/TEOS SACVD reaction according to an exemplary embodiment of the present invention.

### DETAILED DESCRIPTION OF THE INVENTION

Deposition methods for silicon oxide films with improved pattern loading characteristics are described. These methods use sub-atmospheric chemical vapor depositions (SACVD) of silicon oxide from ozone and silicon-containing precursors (e.g., TEOS). The deposition processes include exposing a deposition substrate to a mixture of the ozone and silicon-containing precursor at high total pressures (e.g., about 100 Torr or more) and low temperatures (e.g., about 250° C. to about 325° C.). These conditions provide for an oxide film deposition rate that is dominated by the reaction rate of the deposition precursors (e.g., O₃ and TEOS) at the deposition surface (i.e., surface dominated) instead of the rate at which the precursors can be transported to the surface (i.e., mass dominated).

In surface dominated depositions, there is improved pattern loading of the deposited film. Pattern loading refers to a measure of the thickness variation between areas of dense and open structures in the substrate surface. Increased pattern loading means there is an increased variation in the thickness between these areas. Typically, pattern loading is high for mass dominated processes, where the deposited film is often thicker in open areas than areas having more densely packed substrate structures (e.g., gaps and steps on the substrate). This is caused, in part, by the differences in exposed surface area; a densely structured area has a larger deposition surface area than an open area on which the film is deposited. For mass dominated processes, where the same amount of material reaches the equal-sized areas on the substrate that material gets more spread out (and spread thinner) on the more densely structured regions of the substrate.

In contrast, the differences in deposition surface areas has a smaller effect on surface dominated depositions. In surface dominated depositions, a low temperature at the reaction surface slows the chemical reaction rate of the deposition precursors to make this the rate limiting step of the deposition instead of the rate at which the precursors can reach the surface (i.e., mass dominated depositions). Because the reaction rate is the same for both open and densely packed substrate regions, the buildup of the deposited film is the same in both regions which improves (i.e., reduces) pattern loading during the deposition.

An application for these low-temperature depositions with improved pattern loading is the formation of sacrificial oxide layers in lithographic patterning processes. For example, a low-temperature O₃+TEOS deposition may be used to deposit conformal oxide layer films of substantially uniform thickness over open and dense step patterns formed on or in a silicon wafer substrate. The patterns may include protruding steps and/or gaps formed on a planar substrate surface with a resist material. Because O₃ is used as a deposition reactant the resist material may include inorganic elements and/or compounds, such as silicon, oxygen and/or nitrogen. For example, the material may be polysilicon, or a dielectric silicon oxide, nitride and/or oxynitride.

Specific patterning applications that can make use of the low-temperature sacrificial oxide film deposition methods include spacer dual patterning photolithographic techniques. In spacer dual patterning, the sacrificial oxide forms a conformal film around patterned photoresist structures. The film is then partially etched to “open” those portions covering the tops of the photoresist structures. The photoresist material is then removed to leave sacrificial oxide structures that define a pattern on the underlying substrate. Portions of the substrate that are not covered by the oxide may then be etched to form a pattern of gaps in the substrate. The sacrificial oxide may then be removed from the etched substrate. Additional details about spacer dual patterning techniques may be found a U.S. Provisional patent application by Zheng et al, filed the same day as the present application, and titled “OXYGEN SACVD TO FORM SACRIFICIAL OXIDE LINERS IN SUBSTRATE GAPS” the entire contents of which is herein incorporated by reference.

### Exemplary Deposition Process

Exemplary deposition processes include Sub-Atmospheric Chemical Vapor Deposition (SACVD) processes, which include, but are not limited to, High Aspect Ratio Processes (HARP). The deposition processes may include introducing an silicon-containing precursor (e.g., silane, an organo-silane or organo-siloxane precursor such as tetraethylorthosilicate (TEOS), trimethylsilane, tetramethylsilane, dimethylsilane, diethylsilane, tetramethylcyclotetrasiloxane, etc.) and an oxidizer gas that includes ozone (O₃) into a deposition chamber and chemically reacting them to deposit a sacrificial silicon oxide film on a deposition substrate.

The SACVD processes may also include introducing an inert gas and/or carrier gas to the deposition chamber. Carrier gases carry the silicon precursor and/or oxygen to the deposition chamber, and inert gases help maintain the chamber at a particular pressure. Both types of gases may include helium, argon, and/or nitrogen (N₂), among other kinds of gases.

The flow rates for the reactive precursors and carrier/inert gases may be controlled to provide the appropriate partial pressures of gases in the deposition chamber. In embodiments processing 200-mm substrates, in a deposition that uses TEOS as the silicon-containing precursor with ozone, the TEOS may flow at a rate of about 2500 to about 4000 mgm, the ozone may flow at about 1 slm to about 5 slm (e.g., about 1.5 slm to about 3 slm) (with the ozone concentration being about 6 to about 12% wt. of the oxidizing gas), helium may flow at about 15 slm, nitrogen may flow at about 5 slm, and additional nitrogen (N2) from, for example, an RPS may flow at a rate of about 500 slm. The deposition process can be performed in PRODUCER™ CVD chambers/systems, available from Applied Materials, Inc. of Santa Clara, Calif. The deposition substrate may be spaced about 200 mils to about 900 mils (e.g., about 250 mils to about 325 mils) from a showerhead faceplate where the precursors enter the deposition chamber. In embodiments, the deposition substrate may be spaced about 600 mils from the showerhead faceplate. It is noted that the flow rates of the gases described above can be modified for processing substrates with different sizes. For example, the flow rates of the gases for processing 300-mm substrates can be about 2.25 times of those for processing 200-nm substrates. Based on the description of the application, one of ordinary skill in the art can modify the flow rates and/or other parameters to deposit a desired dielectric film.

The combination of the inert/carrier gases and the deposition precursors (e.g., TEOS and O₃) may be used to set the pressure of the deposition chamber to a range of about 100 Torr to about 760 Torr. Exemplary pressures include about 300 Torr, 400 Torr, 500 Torr, 600 Torr, etc.

As noted above, sacrificial oxide depositions using TEOS and ozone may be conducted at low temperatures (e.g., about 250° C. to about 325° C.; about 250° C.; about 300° C.; etc.). Examples include depositing the sacrificial oxide film at a temperature from about 300° C. until the film reaches a thickness of about 50 Å to about 600 Å. The pressure, temperature and precursor flow conditions may be adjusted such that the film is deposited at a rate from about 1 Å/min to about 600 Å/min. (e.g., about 50 Å/min to about 300 Å/min). Additional details of SACVD dielectric depositions (and in particular SACVD HARP depositions) are described in U.S. Pat. No. 6,905,940 to Ingle et al, titled “METHOD USING TEOS RAMP-UP DURING TEOS/OZONE CVD FOR IMPROVED GAPFILL,” the entire contents of which are herein incorporated by reference for all purposes.

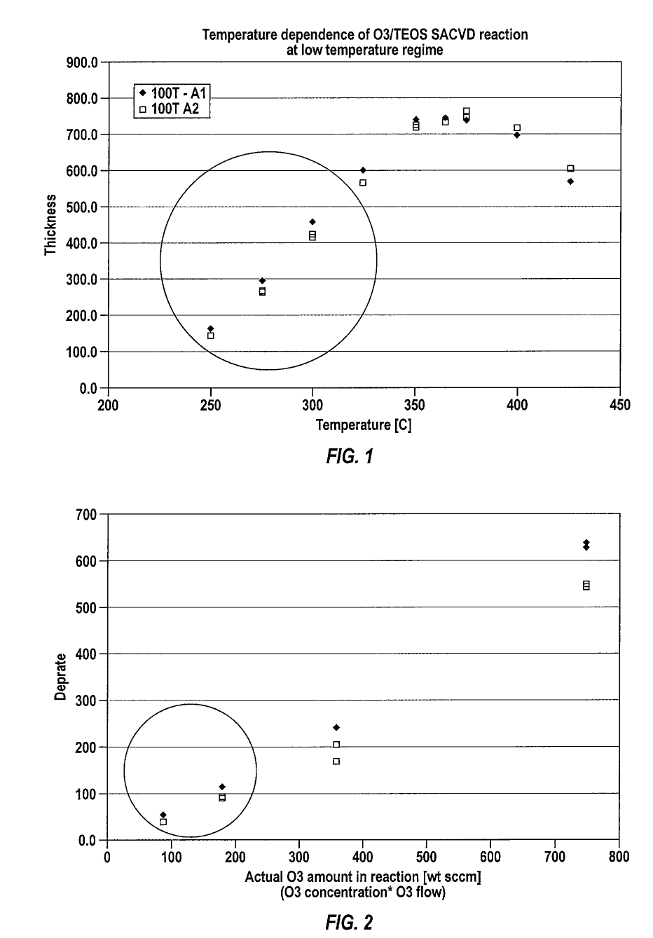

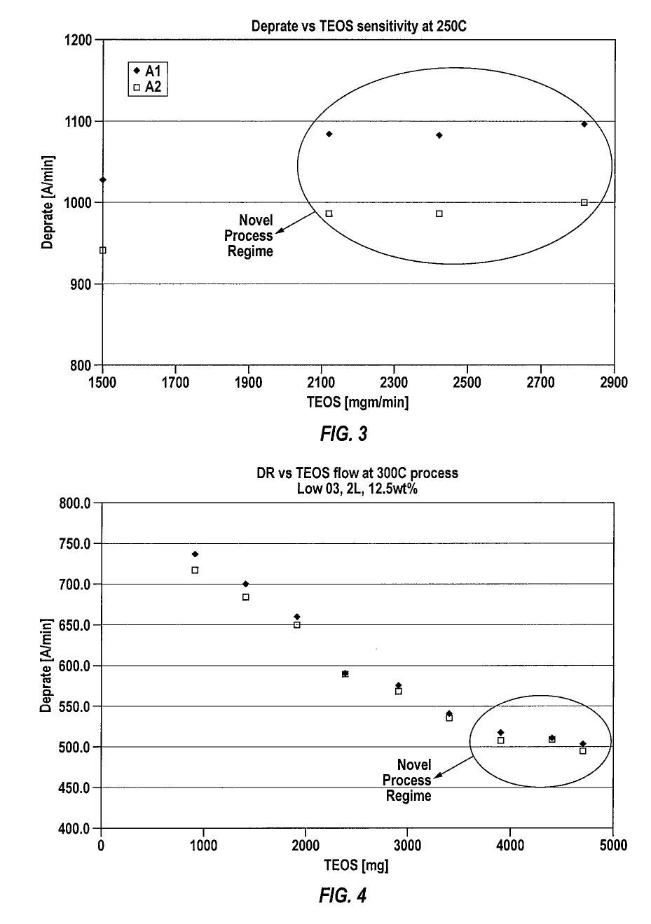

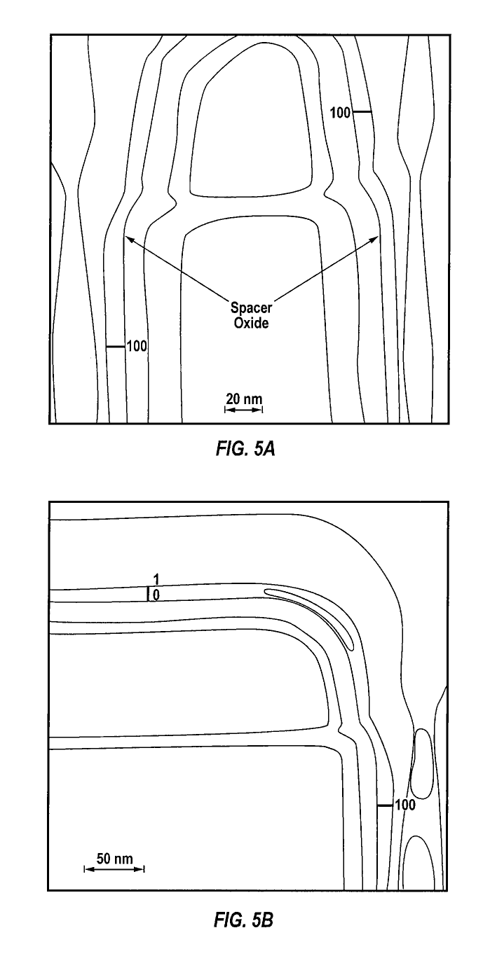

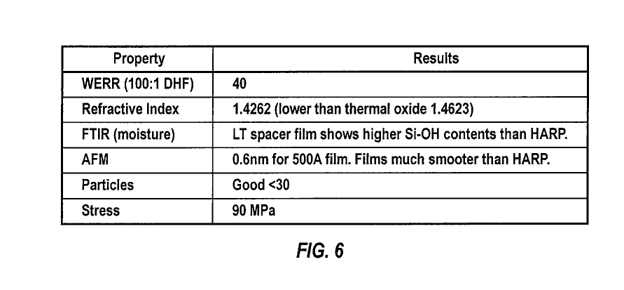

Based on the descriptions set forth above, it is found that a desired processing temperature, such as from about 250° C. to about 325° C., of an exemplary O₃/TEOS SACVD reaction can be identified as shown in FIG. 1. In embodiments, the flow rate of O₃ from about 20 sccm to about 300 sccm can provide a desired deposition rate as shown in FIG. 2. It is found that a substantial flat regime of the deposition rates of the thin film can be shown in FIGS. 3 and 4. In FIG. 3, the exemplary process has a processing temperature of about 250° C. In FIG. 4, the exemplary process has a processing temperature of about 300° C., and the O₃ has an amount of about 2 L and 12.5%, by weight. As shown in FIGS. 3 and 4, the deposition rates of thin films within the flat regime are substantially independent from the flow rates of TEOS. FIGS. 5A and 5B are TEM images showing conformity of thin film deposition at a dense area and open area, respectively. By performing the deposition process within a window, such as temperature from about 250° C. to about 325° C., O₃ amount from about 1.5 L to about 3 L, O₃ concentration from about 6%, by weight to about 12%, by weight, and TEOS flow rate from about 2,500 mg to about 4,000 mg, a desired conformity of the thin film can be achieved as shown in FIGS. 5A and 5B. FIG. 6 is a table showing characteristics of a thin film formed within the flat regime shown in FIG. 3 or 4 having O₃ amount of about 2 L and a processing temperature of about 300° C.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

As used herein and in the appended claims, the singular forms “a”, “and”, and “the” include plural referents unless the context clearly dictates otherwise. Thus, for example, reference to “a process” may includes a plurality of such processes and reference to “the layer” may include reference to one or more layers and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, or groups.

What is claimed is:

1. A method of improving pattern loading in a deposition of a silicon oxide film, the method comprising:
providing a deposition substrate to a deposition chamber;
adjusting a temperature of the deposition substrate to about 250° C. to about 325° C.;
introducing an ozone containing gas to the deposition chamber at a first flow rate of about 1.5 slm to about 3 slm, wherein the ozone concentration in the gas is about 6% to about 12%, by wt.; and
introducing TEOS into the deposition chamber at a second flow rate of about 2500 mgm to about 4500 mgm, wherein a deposition rate of the silicon oxide film is controlled by a reaction rate of a reaction of the ozone and TEOS at a deposition surface of the substrate.

2. The method of claim 1, wherein the deposition rate of the silicon oxide film is independent of the second flow rate for the TEOS.

3. The method of claim 1, wherein the deposition rate of the silicon oxide film is about 50 Å/min to about 300 Å/min.

4. The method of claim 1, wherein the silicon oxide film has a thickness of about 50 Å to about 650 Å.

5. The method of claim 1, wherein the temperature of the substrate is about 300° C. during the deposition.

6. The method of claim 1, wherein the temperature of the substrate is about 250° C. during the deposition.

7. The method of claim 1, wherein the silicon oxide film has a WERR of about 40.

8. A method of forming and removing a sacrificial oxide layer, the method comprising:
forming a step on a substrate, wherein the step has a top and sidewalls;
forming a sacrificial oxide layer around the step by chemical vapor deposition of ozone and a silicon-precursor, wherein the oxide layer is formed on the top and sidewalls of the step;
removing a top portion of the oxide layer and the step;
removing a portion of the substrate exposed by the removal of the step to form a etched substrate; and
removing the entire sacrificial oxide layer from the etched substrate.

9. The method of claim 8, wherein the step comprises an inorganic material.

10. The method of claim 9, wherein the step comprises silicon.

11. The method of claim 8, wherein the silicon-containing precursor comprises an organo-silane or organo-siloxane compound.

12. The method of claim 8, wherein the silicon-containing precursor comprises TEOS.

13. The method of claim 8, wherein the substrate is heated to a temperature of about 250° C. to about 325° C. during the formation of the sacrificial oxide layer.

14. The method of claim 8, wherein the substrate is heated to a temperature of about 300° C. during the formation of the sacrificial oxide layer.

15. The method of claim 8, wherein a total pressure in the deposition chamber is at least 500 Torr during the formation of the sacrificial oxide layer.

16. The method of claim 8, wherein the sacrificial oxide layer has a thickness of about 200 Å to about 600 Å when deposited.

17. The method of claim 8, wherein the sacrificial oxide layer is deposited at a rate of about 50 Å/min to about 800 Å/min.

18. The method of claim 8, wherein the silicon-containing precursor has a flow rate of about 2500 to about 4500 mgm and the ozone has a flow rate of about 1.5 slm to about 3 slm during the formation of the sacrificial oxide layer.

19. The method of claim 8, wherein the sacrificial oxide layer is removed by a dry chemical etch using a fluorine etchant.

20. The method of claim 1, wherein the silicon oxide film has a WERR of about 40.

21. A method to incorporate a sacrificial oxide layer in a semiconductor gap formation process, the method comprising:
forming a photoresist layer on a substrate;
patterning the photoresist layer to form a step structure;
forming the sacrificial oxide layer around the step structure by chemical vapor deposition of ozone and a silicon-containing precursor;
removing a top portion of the oxide layer to form unconnected first and second oxide structures on opposite sidewalls of the step structure;
removing the step structure between the oxide structures;
removing a portion of the underlying substrate that is not covered by the oxide structures to form an etched gap in the substrate; and
removing the oxide structures from the etched substrate.

22. The method of claim 21, wherein the silicon-containing precursor is TEOS.

23. The method of claim 21, wherein the substrate is heated to a temperature of about 250° C. to about 325° C. during the formation of the sacrificial oxide layer.

24. The method of claim 21, wherein a total pressure in the deposition chamber is about 600 Torr or more during the formation of the sacrificial oxide layer.

25. The method of claim 21, wherein the sacrificial oxide layer has a WERR of about 40.

26. The method of claim 21, wherein the step comprises an inorganic material.

27. The method of claim 21, wherein the step comprises silicon.

28. The method of claim 21, wherein the step comprises silicon oxide or silicon nitride.
